(19) United States
(12) Patent Application Publication
(10) Pub. No.: US 2026/0341315 A1
(43) Pub. Date: Oct. 29, 2026

(54) SEMICONDUCTOR DEVICE

(71) Applicant: SK hynix Inc., Gyeonggi-do (KR)

(72) Inventor: Young Ock HONG, Gyeonggi-do (KR)

(21) Appl. No.: 19/331,929

(22) Filed: Sep. 17, 2025

(30) Foreign Application Priority Data
Apr. 23, 2025 (KR) 10-2025-0052993

(51) Int. Cl. G11C 5/06; G11C 16/04; G11C 16/26; H10B 41/10; H10B 41/35; H10B 41/41; H10B 43/10; H10B 43/35; H10B 43/40; H10D 80/30; H10W 90/00

(52) U.S. Cl. CPC G11C 5/063; G11C 16/0483; G11C 16/26; H10B 41/10; H10B 41/35; H10B 41/41; H10B 43/10; H10B 43/35; H10B 43/40; H10D 80/30; H10W 90/00; H10W 90/792

(57) ABSTRACT

A semiconductor device includes a first semiconductor structure including a first memory string, a first even bit line, and a first odd bit line; a second semiconductor structure bonded to the first semiconductor structure and including a second memory string, a second even bit line, and a second odd bit line, and a third semiconductor structure bonded to the first semiconductor structure and including an even page buffer shared by the first even bit line and the second even bit line, an odd page buffer shared by the first odd bit line and the second odd bit line, and a peripheral circuit located between the even page buffer and the odd page buffer.

### CROSS-REFERENCE TO RELATED APPLICATION

This application claims priority under 35 U.S.C. §119 to Korean Patent Application No. 10-2025-0052993 filed on Apr. 23, 2025, which is incorporated herein by reference in its entirety.

### BACKGROUND

### Technical Field

Embodiments of the present disclosure relate generally to an electronic device, and more particularly, to a semiconductor device.

### RELATED ART

The degree of integration of a semiconductor device is mainly determined by the area occupied by a unit memory cell. Recently, as advancements in the integration of semiconductor devices—where memory cells are formed in a single layer on a substrate—have approached their physical limits, three-dimensional semiconductor devices that stack memory cells on a substrate have been proposed. Furthermore, to enhance the operational reliability of such semiconductor devices, various structures and manufacturing methods have been developed. However, further improvements are still required to meet the growing demand for more compact and higher-performance semiconductor devices.

According to embodiments of the present disclosure an improved three-dimensional semiconductor device (hereinafter referred to simply as a semiconductor device) is provided.

Some advantages of the embodiments provide a semiconductor device having a stable structure and improved characteristics. Accordingly, in an embodiment of the present disclosure, a semiconductor device may include a first semiconductor structure including a first memory string, a first even bit line, and a first odd bit line; a second semiconductor structure bonded to the first semiconductor structure and including a second memory string, a second even bit line, and a second odd bit line; and a third semiconductor structure bonded to the first semiconductor structure and including an even page buffer shared by the first even bit line and the second even bit line, an odd page buffer shared by the first odd bit line and the second odd bit line, and a peripheral circuit located between the even page buffer and the odd page buffer.

In another embodiment of the present disclosure, a semiconductor device may include a first semiconductor structure including a first memory string, a first even bit line, a first odd bit line, a first dummy bit line, and a second dummy bit line; a second semiconductor structure bonded to the first semiconductor structure and including a second memory string, a second even bit line, and a second odd bit line; and a third semiconductor structure bonded to the first semiconductor structure and including an even page buffer shared by the first even bit line and the second even bit line and an odd page buffer shared by the first odd bit line and the second odd bit line, wherein the second odd bit line may be connected to the odd page buffer through the first dummy bit line.

These and other features and advantages of the embodiments of the present disclosure will become better understood by those with ordinary skill in the art from the following drawings and detailed description.

### BRIEF DESCRIPTION OF THE DRAWINGS

FIGS. 1A and 1B are diagrams illustrating the structure of a semiconductor device in accordance with an embodiment of the present disclosure.

FIG. 2 is a diagram illustrating the structure of a semiconductor device in accordance with an embodiment of the present disclosure.

FIGS. 3A and 3B are diagrams illustrating the structure of a semiconductor device in accordance with an embodiment of the present disclosure.

FIGS. 4A and 4B are diagrams illustrating the structure of a semiconductor device in accordance with an embodiment of the present disclosure.

FIGS. 5A and 5B are diagrams illustrating the structure of a semiconductor device in accordance with an embodiment of the present disclosure.

FIG. 6 is a diagram illustrating the structure of a semiconductor device in accordance with an embodiment of the present disclosure.

FIG. 7 is a diagram illustrating the structure of a semiconductor device in accordance with an embodiment of the present disclosure.

FIG. 8 is a configuration diagram of a semiconductor device in accordance with an embodiment of the present disclosure.

FIG. 9 is a configuration diagram of a semiconductor device in accordance with an embodiment of the present disclosure.

### DETAILED DESCRIPTION

Various embodiments of the present disclosure are directed to a semiconductor device having a stable structure and improved characteristics and a method of manufacturing the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

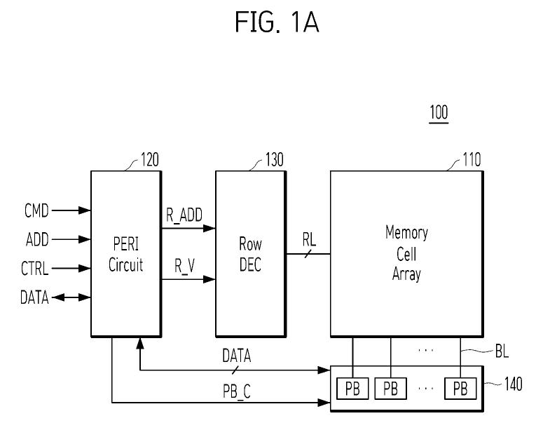

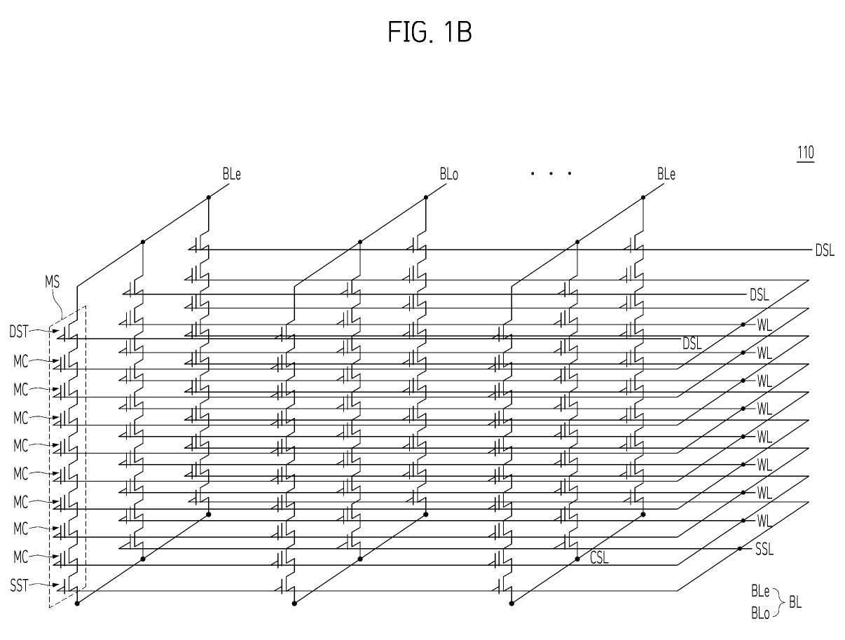

FIGS. 1A and 1B are diagrams illustrating the structure of a semiconductor device in accordance with an embodiment of the present disclosure. FIG. 1A is a block diagram illustrating the configuration of the semiconductor device, and FIG. 1B is a circuit diagram illustrating the configuration of a memory cell array.

Referring to FIGS. 1A and 1B, the semiconductor device 100 in accordance with an embodiment may include a memory cell array 110, a peripheral circuit 120, a row decoder 130, and a read and write circuit 140.

The memory cell array 110 may include memory cells MC. The memory cells MC may be volatile memory cells or nonvolatile memory cells. For example, the memory cell array 110 may include a first memory cell array and a second memory cell array connected to each other by a bonding structure. The memory cell array 110 may include memory blocks, each of which may include memory strings MS. Each of the memory strings MS may include at least one drain select transistor DST, a plurality of memory cells MC, and at least one source select transistor SST connected to each other in series.

The memory cell array 110 may be connected to the row decoder 130 through row lines RL. The row lines RL may include at least one drain select line DSL, a plurality of word lines WL, and at least one source select line SSL. The memory cell array 110 may be connected to the read and write circuit 140 through bit lines BL.

The row decoder 130 may select one of the memory blocks included in the memory cell array 110 in response to a row address R_ADD provided from the peripheral circuit 120. The row decoder 130 may transmit an operating voltage R_V provided from the peripheral circuit 120 to the memory cell array 110 through the row lines RL.

The read and write circuit 140 may include a plurality of page buffers PB respectively connected to the bit lines BL. For example, the bit lines BL may include an odd bit line BLo and an even bit line BLe, and the read and write circuit 140 may include an odd page buffer and an even page buffer. The read and write circuit 140 may receive a page buffer control signal PB_C from the peripheral circuit 120, and may transmit and receive a data signal DATA to and from the peripheral circuit 120. The read and write circuit 140 may control the bit lines BL in response to the page buffer control signal PB_C. The read and write circuit 140 may write data to or read data from a memory cell MC connected to an activated word line.

During a program operation, the read and write circuit 140 may operate as a write driver. For example, the read and write circuit 140 may apply a signal to the bit line BL based on the data signal DATA received from the peripheral circuit 120 in response to the page buffer control signal PB_C, and may accordingly write data to the memory cell MC of the memory cell array 110.

During a read or verify operation, the read and write circuit 140 may operate as a sense amplifier. For example, the read and write circuit 140 may detect data stored in the memory cell of the memory cell array 110 by sensing a signal of the bit line BL in response to the page buffer control signal PB_C, and may transmit the data signal DATA to the peripheral circuit 120 according to the detected data.

The peripheral circuit 120 may receive a command signal CMD, an address signal ADD, and a control signal CTRL from a controller, and may also transmit and receive data DATA to and from the controller. Based on the received CMD, ADD, and CTRL signals, the peripheral circuit 120 may output signals for writing data to the memory cell array 110 or reading data from the memory cell array 110.

To support the internal functions of the semiconductor device 100, the peripheral circuit 120 may be configured to generate various internal voltages. The peripheral circuit 120 may generate internal voltages of various voltage levels required by the semiconductor device 100 to perform an internal operation, and may provide the generated internal voltages to the row decoder 130. The internal voltage may be the operating voltage R_V for performing the program operation, the read operation, an erase operation, or the like.

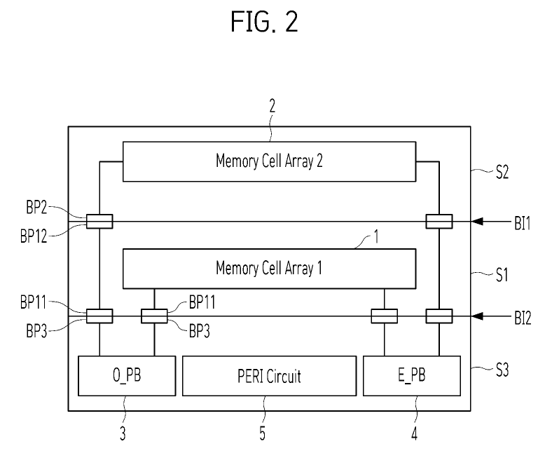

FIG. 2 is a diagram illustrating the structure of a semiconductor device in accordance with an embodiment of the present disclosure. Hereinafter, content overlapping with previously described content may be omitted.

Referring to FIG. 2, the semiconductor device may include a first, second, and third semiconductor structures S1, S2, and S3. The first semiconductor structure S1 may include a first memory cell array 1, the second semiconductor structure S2 may include a second memory cell array 2, and the third semiconductor structure S3 may include an odd page buffer 3, an even page buffer 4, and a peripheral circuit 5.

The first semiconductor structure S1 may be located between the second and third semiconductor structures S2 and S3. The first and second semiconductor structures S1 and S2 may be in contact with each other with a first bonding interface BI1 interposed therebetween. The first semiconductor structure S1 and the second semiconductor structure S2 may be electrically connected to each other through a first bonding pad BP12 of the first semiconductor structure S1 and a second bonding pad BP2 of the second semiconductor structure S2.

The first semiconductor structure S1 and the third semiconductor structure S3 may contact each other with a second bonding interface BI2 interposed therebetween. The first semiconductor structure S1 and the third semiconductor structure S3 may be electrically connected to each other through a first bonding pad BP11 of the first semiconductor structure S1 and a third bonding pad BP3 of the third semiconductor structure S3. In addition, the second semiconductor structure S2 and the third semiconductor structure S3 may be electrically connected to each other through the second bonding pad BP2, the first bonding pad BP12, the first bonding pad BP11, and the third bonding pad BP3.

According to the structure described above, the odd page buffer 3 may be shared by the first memory cell array 1 and the second memory cell array 2. The even page buffer 4 may be shared by the first memory cell array 1 and the second memory cell array 2. The peripheral circuit 5 may be located between the odd page buffer 3 and the even page buffer 4.

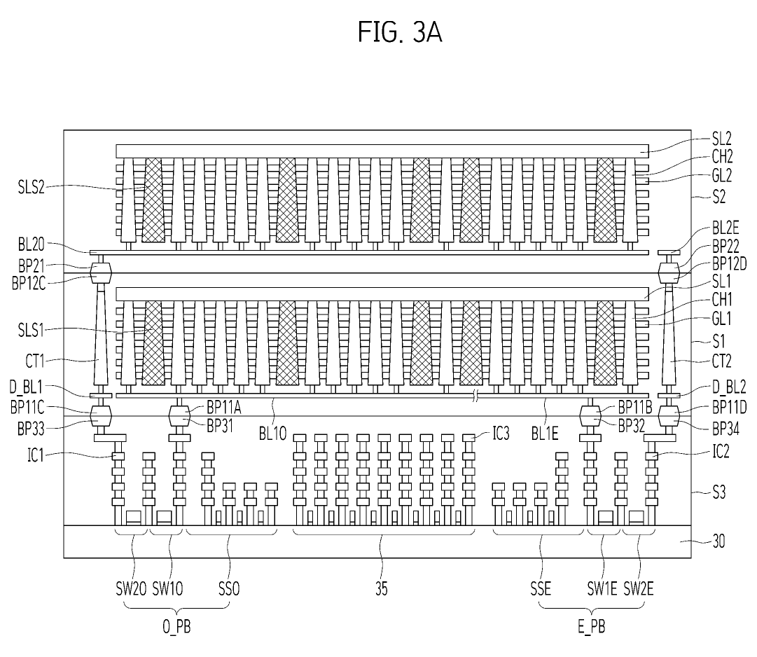

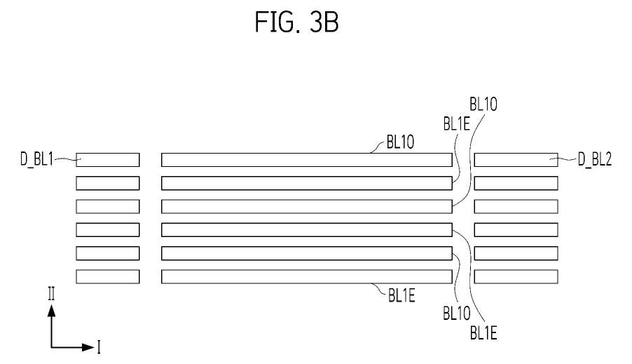

FIGS. 3A and 3B are diagrams illustrating the structure of a semiconductor device in accordance with an embodiment of the present disclosure. Hereinafter, content overlapping with previously described content may be omitted.

Referring to FIG. 3A, the semiconductor device may include a first, second, and third semiconductor structures S1, S2, and S3. The first semiconductor structure S1 may include a first memory cell array, and the second semiconductor structure S2 may include a second memory cell array.

The first semiconductor structure S1 may include first gate lines GL1, first channel structures CH1, first slit structures SLS1, a first source line SL1, a first contact plug CT1, a second contact plug CT2, first odd bit lines BL1O, first even bit lines BL1E, first dummy bit lines D_BL1, second dummy bit lines D_BL2, and first bonding pads BP11A, BP11B, BP11C, BP11D, BP12C, and BP12D.

The first channel structures CH1 and the first slit structures SLS1 may extend through the stacked first gate lines GL1. The first gate lines GL1 may be source select lines, word lines, or drain select lines. Each of the first channel structures CH1 may include a channel layer, a memory layer surrounding the channel layer, and an insulating core located in the channel layer. The first slit structures SLS1 may each include an insulating material, a semiconductor material, or a conductive material.

The first source line SL1 may be located above the first gate lines GL1 while the first odd bit lines BL1O and the first even bit lines BL1E may be located below the first gate lines GL1. Alternatively, the first source line SL1 may be located below the first gate lines GL1 while the first odd bit lines BL1O and the first even bit lines BL1E may be located above the first gate lines GL1.

Referring to FIGS. 3A and 3B, the first odd bit lines BL1O and the first even bit lines BL1E may extend along a first direction I. The first odd bit lines BL1O and the first even bit lines BL1E may be alternately arranged along a second direction II intersecting the first direction I. The first dummy bit lines D_BL1 may be located at the same or substantially the same level as the first odd bit lines BL1O, and the second dummy bit lines D_BL2 may be located at the same or substantially the same level as the first even bit lines BL1E.

The second semiconductor structure S2 may include second gate lines GL2, second channel structures CH2, second slit structures SLS2, a second source line SL2, second odd bit lines BL2O, second even bit lines BL2E, and second bonding pads BP21 and BP22. The second channel structures CH2 and the second slit structures SLS2 may extend through the stacked second gate lines GL2. The second gate lines GL2 may be source select lines, word lines, or drain select lines. Each of the second channel structures CH2 may include a channel layer, a memory layer surrounding the channel layer, and an insulating core located in the channel layer. The second slit structures SLS2 may each include an insulating material, a semiconductor material, or a conductive material.

As illustrated in FIG. 3A, the second source line SL2 may be located above the second gate lines GL2, and the second odd bit lines BL2O and the second even bit lines BL2E may be located below the second gate lines GL2. Alternatively, the second source line SL2 may be located below the second gate lines GL2, and the second odd bit lines BL2O and the second even bit lines BL2E may be located above the second gate lines GL2. The second odd bit lines BL2O and the second even bit lines BL2E may be alternately arranged.

The third semiconductor structure S3 may include a substrate 30, an odd page buffer O_PB, an even page buffer E_PB, a peripheral circuit 35, a first interconnection structure IC1, a second interconnection structure IC2, a third interconnection structure IC3, and third bonding pads BP31, BP32, BP33, and BP34. The peripheral circuit 35 may be located between the odd page buffer O_PB and the even page buffer E_PB. The first interconnection structure IC1 may be connected to the odd page buffer O_PB, the second interconnection structure IC2 may be connected to the even page buffer E_PB, and the third interconnection structure IC3 may be connected to the peripheral circuit 35.

The odd page buffer O_PB may include a first odd switch SW1O, a second odd switch SW2O, and an odd sensing unit SSO. The even page buffer E_PB may include a first even switch SW1E, a second even switch SW2E, and an even sensing unit SSE.

The first odd bit line BL1O may be connected to the first odd switch SW1O through the first bonding pad BP11A, the third bonding pad BP31, and the first interconnection structure IC1. The first odd switch SW1O may be connected to the odd sensing unit SSO through the first interconnection structure IC1.

The second odd bit line BL2O may be connected to the second odd switch SW2O through the second bonding pad BP21, the first bonding pad BP12C, the first contact plug CT1, the first dummy bit line D_BL1, the first bonding pad BP11C, the third bonding pad BP33, and the first interconnection structure IC1. The second odd switch SW2O may be connected to the odd sensing unit SSO through the first interconnection structure IC1.

The first even bit line BL1E may be connected to the first even switch SW1E through the first bonding pad BP11B, the third bonding pad BP32, and the second interconnection structure IC2. The first even switch SW1E may be connected to the even sensing unit SSE through the second interconnection structure IC2.

The second even bit line BL2E may be connected to the second even switch SW2E through the second bonding pad BP22, the first bonding pad BP12D, the second contact plug CT2, the second dummy bit line D_BL2, the first bonding pad BP11D, the third bonding pad BP34, and the second interconnection structure IC2. The second even switch SW2E may be connected to the even sensing unit SSE through the second interconnection structure IC2.

According to the structure described above, the odd page buffer O_PB may be shared by the first odd bit line BL1O and the second odd bit line BL2O. The even page buffer E_PB may be shared by the first even bit line BL1E and the second even bit line BL2E. The odd and even page buffers O_PB and E_PB may be distributed and disposed at opposite edges of a memory plane with the peripheral circuit disposed at the center of the memory plane. As a result, even when the first semiconductor structure S1 and the second semiconductor structure S2 are bonded to each other, an area occupied by a page buffer may not increase, although the pitch may be increased. Hence, this configuration enables efficient resource sharing and spatial optimization within the memory plane.

In addition, the second odd bit lines BL2O may be connected to the odd page buffer O_PB using the first dummy bit line D_BL1 of the first semiconductor structure S1. The second even bit lines BL2E may be connected to the even page buffer E_PB using the second dummy bit line D_BL2 of the first semiconductor structure S1. The first and second dummy bit lines D_BL1 and D_BL2 may be formed together with the first odd bit lines BL1O and the first even bit lines BL1E when the first odd bit lines BL1O and the first even bit lines BL1E are formed. Accordingly, even though the first semiconductor structure S1 and the second semiconductor structure S2 are bonded to each other, the second semiconductor structure S2 may be connected to the third semiconductor structure S3 without adding an wiring line process.

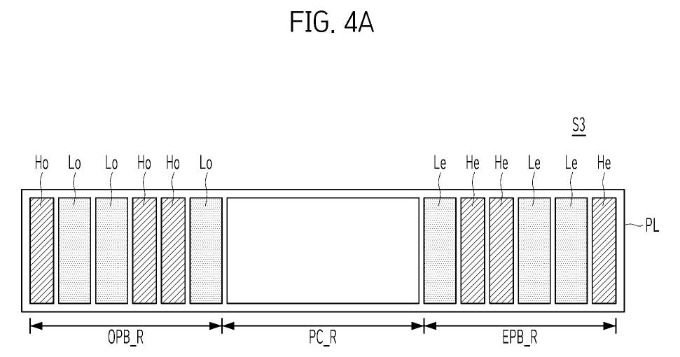

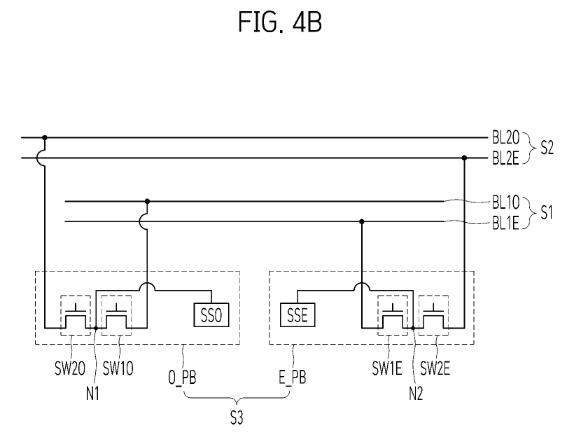

FIGS. 4A and 4B are diagrams illustrating the structure of a semiconductor device in accordance with an embodiment of the present disclosure. FIG. 4A illustrates a layout of a third semiconductor structure S3, and FIG. 4B illustrates the connection between a page buffer and bit lines. Hereinafter, content overlapping with previously described content may be omitted.

Referring to FIGS. 4A and 4B, the third semiconductor structure S3 may include an odd page buffer region OPB_R, an even page buffer region EPB_R, and a peripheral circuit region PC_R disposed between the odd and even page buffer regions OBP_R and EPB_R. A plurality of odd page buffers O_PB may be located in the odd page buffer region OPB_R. A plurality of even page buffers E_PB may be located in the even page buffer region EPB_R. The peripheral circuit region PC_R located between the odd and even page buffer regions OPB_R and EPB_R may include a peripheral circuit 25.

When comparing a layout of a memory plane PL included in a first semiconductor structure S1 and the layout of the third semiconductor structure S3 with each other, the odd page buffer region OPB_R and the even page buffer region EPB_R may be distributed and disposed at opposite edges of the memory plane PL. The peripheral circuit region PC_R may be located at the center of the memory plane PL.

The odd page buffer region OPB_R may include a plurality of high voltage regions Ho and a plurality of low voltage regions Lo. The high voltage regions Ho and the low voltage regions Lo may be arranged in an alternating sequence of two high voltage regions followed by two low voltage regions. That is, two high voltage regions Ho and two low voltage regions Lo may be alternately arranged, and this arrangement may be repeated as may be needed. The even page buffer region EPB_R may include a plurality of high voltage regions He and a plurality of low voltage regions Le. The high voltage regions He and low voltage regions Le may also be arranged in an alternating pattern of two high voltage regions and two low voltage regions. That is, two high voltage regions He and two low voltage regions Le may be alternately arranged. This arrangement may be repeated as may be needed.

The odd page buffer O_PB may include a first odd switch SW1O, a second odd switch SW2O, and an odd sensing unit SSO. The first odd switch SW1O may control the connection between the odd page buffer O_PB and a first odd bit line BL1O. The second odd switch SW2O may control the connection between the odd page buffer O_PB and a second odd bit line BL2O.

The odd sensing unit SSO is used to sense data of the first odd bit line BL1O and the second odd bit line BL2O, and may include a latch. The odd sensing unit SSO may be connected to a first node N1, and the first node N1 may be connected to the first odd bit line BL1O through the first odd switch SW1O or connected to the second odd bit line BL2O through the second odd switch SW2O.

The first odd switch SW1O and the second odd switch SW2O may be located in the high voltage region Ho, and may include high voltage transistors. The odd sensing unit SSO may be located in the low voltage region Lo, and may include a low voltage transistor. The high voltage transistor may have a greater size and channel length than the low voltage transistor. Even though a high voltage is applied to the first odd bit line BL1O and/or the second odd bit line BL2O during an erase operation, the first and second odd switches SW1O and SW2O including the high voltage transistors may not be damaged. In addition, by turning off the first and second odd switches SW1O and SW2O, it is possible to block the transmission of the high voltage to the odd sensing unit SSO.

The even page buffer E_PB may include a first even switch SW1E, a second even switch SW2E, and an even sensing unit SSE. The first even switch SW1E may control the connection between the even page buffer E_PB and a first even bit line BL1E. The second even switch SW2E may control the connection between the even page buffer E_PB and a second even bit line BL2E.

The even sensing unit SSE may be configured to sense data from the first even bit line BL1E and the second even bit line BL2E. The even sensing unit SSE may sense data of the first even bit line BL1E and the second even bit line BL2E, and may include a latch. The even sensing unit SSE may be connected to a second node N2, and the second node N2 may be connected to the first even bit line BL1E through the first even switch SW1E or connected to the second even bit line BL2E through the second even switch SW2E.

The first even switch SW1E and the second even switch SW2E may be located in the high voltage region He, and may include high voltage transistors. The even sensing unit SSE may be located in the low voltage region Le and may include a low voltage transistor. For example, a high voltage may be applied to the first even bit line BL1E and/or the second even bit line BL2E during the erase operation, and by turning off the first even switch SW1E and the second even switch SW2E, it is possible to block the transmission of the high voltage to the even sensing unit SSE.

According to the configuration described above, the odd page buffer O_PB located in the third semiconductor structure S3 may be shared by the first odd bit line BL1O of the first semiconductor structure S1 and the second odd bit line BL2O of the second semiconductor structure S2. When the first odd switch SW1O is turned on and the second odd switch SW2O is turned off during a read operation, the first odd bit line BL1O is selected. A current of the first odd bit line BL1O is transmitted to the odd sensing unit SSO through the first node N1, and a current level of the first odd bit line BL1O is read through a sensing circuit of the odd sensing unit SSO.

The even page buffer E_PB located in the third semiconductor structure S3 may be shared by the first even bit line BL1E of the first semiconductor structure S1 and the second even bit line BL2E of the second semiconductor structure S2. When the first even switch SW1E is turned on and the second even switch SW2E is turned off during the read operation, the first even bit line BL1E is selected. A current of the first even bit line BL1E is transmitted to the even sensing unit SSE through the second node N2, and a current level of the first even bit line BL1E is read through a sensing circuit of the even sensing unit SSE.

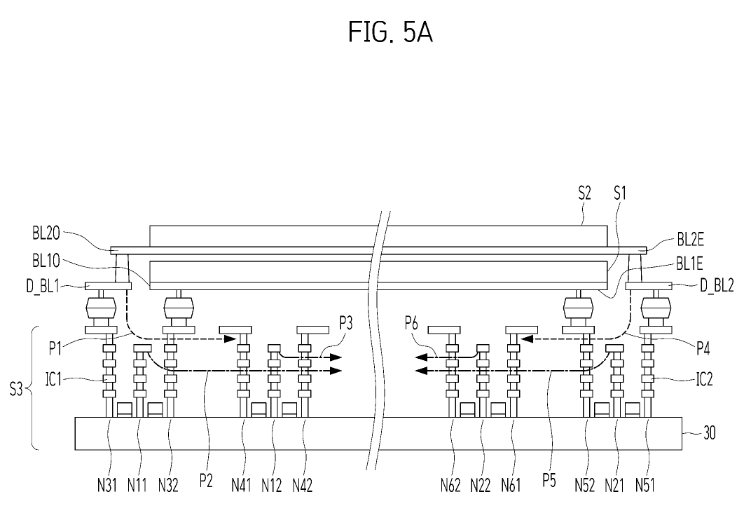

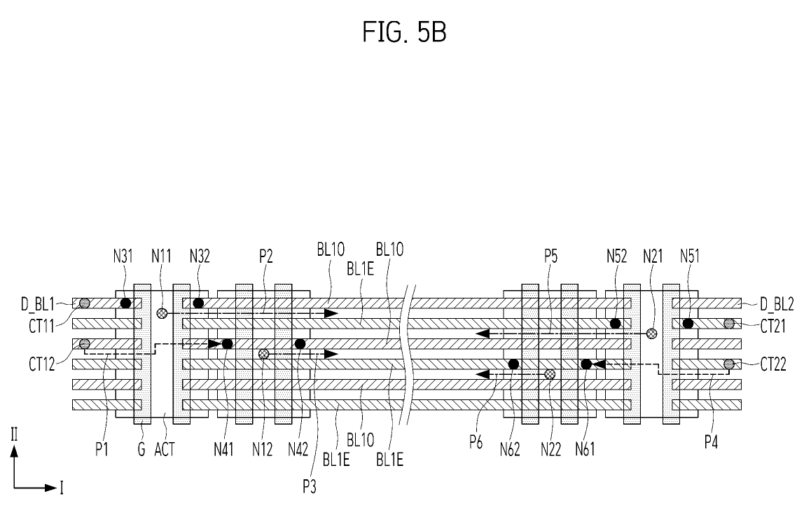

FIGS. 5A and 5B are diagrams illustrating the structure of a semiconductor device in accordance with an embodiment of the present disclosure. Hereinafter, content overlapping with previously described content may be omitted.

Referring to FIGS. 5A and 5B, a semiconductor device may include a first, a second, and a third semiconductor structure S1, S2, and S3. The first semiconductor structure S1 may include first odd bit lines BL1O and first even bit lines BL1E, and the second semiconductor structure S2 may include second odd bit lines BL2O and second even bit lines BL2E.

The third semiconductor structure S3 may include active regions ACT and gate lines G located in a high voltage region. The active regions ACT may be arranged along the first direction I, and the gate lines G may extend along the second direction II. For example, two gate lines G may be located on one active region ACT, and high voltage transistors may be arranged along the first direction I and the second direction II. The high voltage transistors may be a first odd switch SW1O, a second odd switch SW2O, a first even switch SW1E, or a second even switch SW2E.

Because the first semiconductor structure S1 and the third semiconductor structure S3 are arranged to face each other, the first even bit lines BL1E and the first odd bit lines BL1O may be directly connected to their respective target nodes. As used herein, “direct connection” refers to a vertical connection path to a node that does not involve horizontal detouring. Specifically, the first odd bit lines BL1O may be directly connected to a third node N32 and a fourth node N42, while the first even bit lines BL1E may be directly connected to a fifth node N52 and a sixth node N62. This configuration enables efficient vertical interconnection between semiconductor structures, minimizing layout complexity and improving integration density.

Since the first semiconductor structure S1 is positioned between the second semiconductor structure S2 and the third semiconductor structure S3, the second even bit lines BL2E and the second odd bit lines BL2O may be unable to directly connect to their respective target nodes. Instead, these bit lines may be routed to the desired nodes through the first and second interconnection structures IC1 and IC2 provided in the third semiconductor structure S3. This indirect routing allows for effective signal connectivity despite the physical separation, supporting more flexible and densely stacked semiconductor architectures.

The second odd bit line BL2O may be connected to a first dummy bit line D_BL1 through a first contact plug CT11, and may be connected to a third node N31 through the first dummy bit line D_BL1. The second odd bit line BL2O may be connected to the first dummy bit line D_BL1 through a first contact plug CT12, and may be connected to a fourth node N41 through a first bypass path P1. The first bypass path P1 may be provided through the first interconnection structure IC1 of the third semiconductor structure S3.

The second even bit line BL2E may be connected to a second dummy bit line D_BL2 through a second contact plug CT21, and may be connected to a fifth node N51 through the second dummy bit line D_BL2. The second even bit line BL2E may be connected to the second dummy bit line D_BL2 through a second contact plug CT22, and may be connected to a sixth node N61 through a fourth bypass path P4. The fourth bypass path P4 may be provided through the second interconnection structure IC2 of the third semiconductor structure S3.

A first node N11 may be connected to an odd sensing unit SSO through the second path P2 provided through the first interconnection structure IC1. A first node N12 may be connected to the odd sensing unit SSO through a third path P3 provided through the first interconnection structure IC1. A second node N21 may be connected to an even sensing unit SSE through a fifth path P5 provided through the second interconnection structure IC2. A second node N22 may be connected to the even sensing unit SSE through a sixth path P6 provided through the second interconnection structure IC2.

According to the structure described above, the bypass paths may be provided through the first interconnection structure IC1 and the second interconnection structure IC2 of the third semiconductor structure S3. Accordingly, the second odd bit lines BL2O and the second even bit lines BL2E of the second semiconductor structure S2 may be connected to the desired nodes.

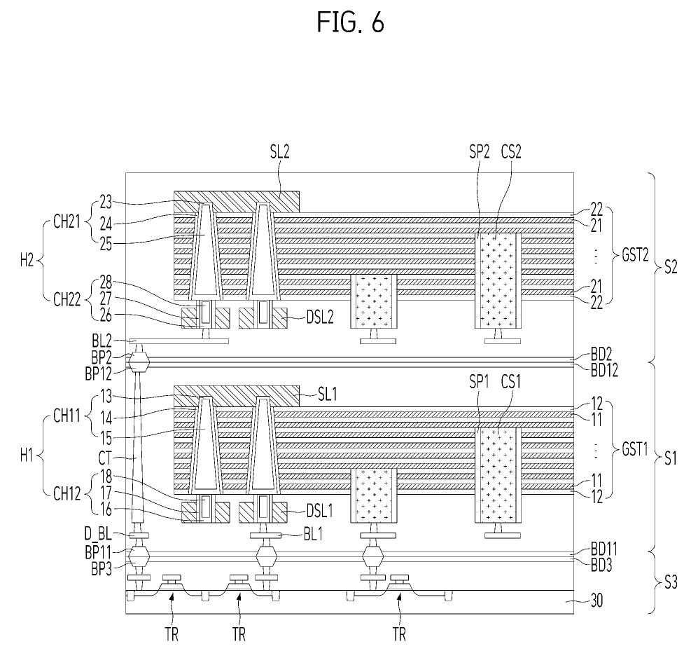

FIG. 6 is a diagram illustrating the structure of a semiconductor device in accordance with an embodiment of the present disclosure.

Referring to FIG. 6, the semiconductor device may include a first, a second, and a third semiconductor structure S1, S2, and S3. The first semiconductor structure S1 may be located between the third semiconductor structure S3 and the second semiconductor structure S2. The first semiconductor structure S1 may be bonded to both the third semiconductor structure S3 and to the second semiconductor structure S2.

The first semiconductor structure S1 may include a first memory cell array. The first semiconductor structure S1 may include a first gate structure GST1, a first source line SL1, a first channel structure CH1, a first drain select line DSL1, a first contact structure CS1, a first insulating spacer SP1, a first bit line BL1, a contact plug CT, a dummy bit line D_BL, first bonding pads BP11 and BP12, and first bonding layers BD11 and BD12.

The first gate structure GST1 may include conductive layers 11 and insulating layers 12 that are alternately stacked. For example, the conductive layers 11 may include at least one first source select line and a plurality of first word lines. The first source line SL1 may be located above the first gate structure GST1. The first drain select line DSL1 may be located below the first gate structure GST1.

The first channel structure CH1 may include a first sub-channel structure CH11 and a second sub-channel structure CH12. The first sub-channel structure CH11 may extend through the first gate structure GST1, and may be connected to the first source line SL1. The second sub-channel structure CH12 may extend through the first drain select line DSL1, and may be connected to the first sub-channel structure CH11 and the first bit line BL1.

The first contact structures CS1 may extend through the first gate structure GST1, and may be connected to the conductive layers 11, respectively. The first insulating spacers SP1 may surround sidewalls of the first contact structures CS1, respectively. These insulating spacers SP1 serve to electrically isolate the contact structures CS1 from adjacent components so that each of the first contact structures CS1 may only contact one conductive layer 11.

The second semiconductor structure S2 may include a second memory cell array. The second semiconductor structure S2 may include a second gate structure GST2, a second source line SL2, a second channel structure CH2, a second drain select line DSL2, a second contact structure CS2, a second insulating spacer SP2, a second bit line BL2, a second bonding pad BP2, and a second bonding layer BD2.

The second gate structure GST2 may include conductive layers 21 and insulating layers 22 that are alternately stacked. For example, the conductive layers 21 may include at least one second source select line and a plurality of second word lines. The second source line SL2 may be located above the second gate structure GST2. The second drain select line DSL2 may be located below the second gate structure GST2.

The second channel structure CH2 may include a first sub-channel structure CH21 and a second sub-channel structure CH22. The first sub-channel structure CH21 may extend through the second gate structure GST2, and may be connected to the second source line SL2. The second sub-channel structure CH22 may extend through the second drain select line DSL2, and may be connected to the first sub-channel structure CH21 and the second bit line BL2.

The second contact structures CS2 may extend through the second gate structure GST2, and may be connected to the conductive layers 21, respectively. The second insulating spacers SP2 may surround sidewalls of the second contact structures CS2, respectively, to ensure that each second contact structure CS2 may be connected with only one of the conductive layers 21.

The third semiconductor structure S3 may include a circuit for driving the first memory cell array and the second memory cell array. For example, the circuit may include a peripheral circuit, an odd page buffer, an even page buffer, and the like. The third semiconductor structure S3 may include a semiconductor substrate 30, transistors TR, a third bonding pad BP3, and a third bonding layer BD3.

The first bonding layer BD11 and the third bonding layer BD3 may be bonded to each other, and the first bonding layer BD12 and the second bonding layer BD2 may be bonded to each other. The first bonding pad BP11 and the third bonding pad BP3 may be electrically connected to each other, and the first bonding pad BP12 and the second bonding pad BP2 may be electrically connected to each other.

According to the structure described above, the first bit line BL1 may be connected to the transistor TR of the third semiconductor structure S3 through the first bonding pad BP11 and the third bonding pad BP3. The second bit line BL2 may be connected to the transistor TR of the third semiconductor structure S3 through the second bonding pad BP2, the first bonding pad BP12, the contact plug CT, the dummy bit line D_BL, the first bonding pad BP11, and the third bonding pad BP3.

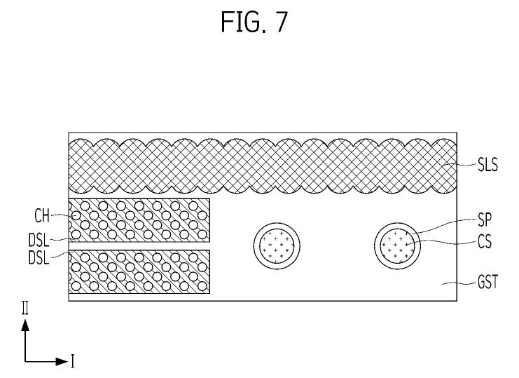

FIG. 7 is a diagram illustrating the structure of a semiconductor device in accordance with an embodiment of the present disclosure.

Referring to FIG. 7, the semiconductor device may include a gate structure GST, a drain select line DSL, a channel structure CH, a slit structure SLS, a contact structure CS, and an insulating spacer SP surrounding the contact structure CS.

The slit structure SLS may extend in the first direction I through the gate structure GST. For example, the slit structure SLS may include irregularities on sidewalls thereof. First, a plurality of holes arranged in the first direction I may be formed at a location where a slit is to be formed. The plurality of holes may be formed simultaneously with channel holes. Subsequently, the slit having irregularities on sidewalls thereof may be formed by expanding the holes to connect the holes to each other. Subsequently, the slit structure SLS may be formed in the slit. For reference, it is also possible for the slit structure SLS to have a line shape without irregularities.

The drain select lines DSL may be adjacent to each other in the second direction II intersecting the first direction I, and may extend along the first direction I. The gate structure GST and the drain select line DSL have been illustrated separately in the present embodiment, but the drain select line DSL may be included in the gate structure GST.

The contact structures CS may have different heights, and may be respectively connected to conductive layers belonging to the gate structure GST. The contact structures CS may extend through the gate structure GST. Alternatively, the gate structure GST may include a staircase structure, and each of pads of the conductive layers may be defined by the staircase structure. In such a case, the contact structures CS may be connected to the pads, respectively.

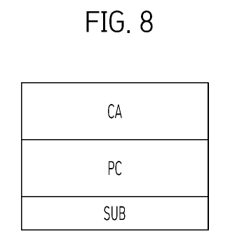

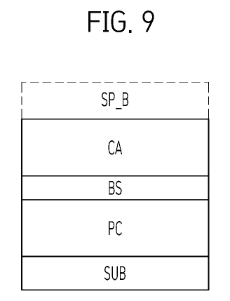

The structure and the manufacturing method according to the above-described embodiments may be applied to semiconductor devices of various structures. FIGS. 8 and 9 illustrate a schematic configuration of a semiconductor device to which the above-described embodiments are applicable.

FIG. 8 is a configuration diagram of a semiconductor device according to an embodiment of the present disclosure.

Referring to FIG. 8, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 9 is a configuration diagram of a semiconductor device according to an embodiment of the present disclosure.

Referring to FIG. 9, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 8.

Additionally, the semiconductor device may have a structure in which the embodiments described above with reference to FIGS. 8 and 9 are combined or may have a partially modified structure. In the embodiment described with reference to FIGS. 8 and 9, positions of the memory cell array CA and the peripheral circuit PC may be changed. At least one memory cell array CA and/or at least one peripheral circuit PC may be additionally bonded to the embodiment described with reference to FIGS. 8 and 9. In an embodiment, a portion of the peripheral circuitry PC may be disposed in the memory cell array CA.

While the above description provides illustrative embodiments in accordance with the technical concepts of the present disclosure, these embodiments are presented solely for descriptive purposes in conjunction with the accompanying drawings. The embodiments of the present disclosure are not limited to the specific embodiments described herein. Various modifications, substitutions, alterations, and combinations of the embodiments may be conceived by those skilled in the art without departing from the scope and technical concepts of the present disclosure, as defined by the following claims. It is to be understood that such modifications and alternatives are encompassed within the scope of the present disclosure.

What is claimed is:

1. A semiconductor device comprising:
a first semiconductor structure including a first memory string, a first even bit line, and a first odd bit line;
a second semiconductor structure bonded to the first semiconductor structure and including a second memory string, a second even bit line, and a second odd bit line; and
a third semiconductor structure bonded to the first semiconductor structure and including an even page buffer shared by the first even bit line and the second even bit line, an odd page buffer shared by the first odd bit line and the second odd bit line, and a peripheral circuit located between the even page buffer and the odd page buffer.

2. The semiconductor device of claim 1, wherein the odd page buffer comprises:
a first odd switch controlling a connection between the first odd bit line and the odd page buffer;
a second odd switch controlling a connection between the second odd bit line and the odd page buffer; and
an odd sensing unit connected to the first odd bit line through the first odd switch or connected to the second odd bit line through the second odd switch.

3. The semiconductor device of claim 2, wherein during a read operation, the first odd switch is turned on, the second odd switch is turned off, and a current of the first odd bit line is transmitted to the odd sensing unit.

4. The semiconductor device of claim 2, wherein the first odd switch and the second odd switch include high voltage transistors.

5. The semiconductor device of claim 2, wherein the odd sensing unit includes a low voltage transistor.

6. The semiconductor device of claim 1, wherein the even page buffer comprises:
a first even switch controlling a connection between the first even bit line and the even page buffer;
a second even switch controlling a connection between the second even bit line and the even page buffer; and
an even sensing unit connected to the first even bit line through the first even switch or connected to the second even bit line through the second even switch.

7. The semiconductor device of claim 6 wherein during a read operation, the first even switch is turned on, the second even switch is turned off, and a current of the first even bit line is transmitted to the even sensing unit.

8. The semiconductor device of claim 6, wherein the first even switch and the second even switch include high voltage transistors.

9. The semiconductor device of claim 6, wherein the even sensing unit includes a low voltage transistor.

10. The semiconductor device of claim 1, wherein the first semiconductor structure further includes a first dummy bit line located at substantially the same level as the first odd bit line, and
wherein the second odd bit line is connected to the odd page buffer through the first dummy bit line.

11. The semiconductor device of claim 1, wherein the first semiconductor structure further includes a second dummy bit line located at substantially the same level as the first even bit line, and
wherein the second even bit line is connected to the even page buffer through the second dummy bit line.

12. A semiconductor device comprising:
a first semiconductor structure including a first memory string, a first even bit line, a first odd bit line, a first dummy bit line, and a second dummy bit line;
a second semiconductor structure bonded to the first semiconductor structure and including a second memory string, a second even bit line, and a second odd bit line; and
a third semiconductor structure bonded to the first semiconductor structure and including an even page buffer shared by the first even bit line and the second even bit line and an odd page buffer shared by the first odd bit line and the second odd bit line,
wherein the second odd bit line is connected to the odd page buffer through the first dummy bit line.

13. The semiconductor device of claim 12, wherein the second even bit line is connected to the even page buffer through the second dummy bit line.

14. The semiconductor device of claim 12, wherein the first odd bit line and the first dummy bit line are located at substantially the same level.

15. The semiconductor device of claim 12, wherein the first even bit line and the second dummy bit line are located at substantially the same level.

16. The semiconductor device of claim 12, wherein the third semiconductor structure further includes a peripheral circuit located between the even page buffer and the odd page buffer.
